(19) United States
(12) Patent Application Publication
(10) Pub. No.: US 2026/0153569 A1
(43) Pub. Date: Jun. 4, 2026

(54) METHOD AND DEVICE FOR MONITORING DC BUS CAPACITOR

(71) Applicant: Delta Electronics, Inc., Taoyuan City (TW)

(72) Inventors: Ting Li, Shanghai (CN); Liuliu Fan, Shanghai (CN); Kai Dong, Shanghai (CN)

(21) Appl. No.: 19/400,595

(22) Filed: Nov. 25, 2025

(30) Foreign Application Priority Data
Nov. 29, 2024 (CN) 202411745268.8

(51) Int. Cl. G01R 31/64; G01R 27/26

(52) U.S. Cl. CPC G01R 31/64; G01R 27/2605

(57) ABSTRACT

The present disclosure provides a monitoring method for monitoring a DC bus capacitor, including steps of: in a preset cycle, sampling an input voltage, an input current and an output voltage to obtain an input power; filtering the input power and the output voltage to obtain an AC component of the input power and an AC component of the output voltage; calculating a capacitance according to the DC component of the output voltage, the AC component of the input power and the AC component of the output voltage; obtaining a total weight coefficient corresponding to the capacitance; and outputting a monitoring capacitance of the DC bus capacitor according to the plurality of the capacitance calculated and obtained in a plurality of the preset cycles and the plurality of the total weight coefficients corresponding to the plurality of capacitance.

### CROSS-REFERENCE TO RELATED APPLICATION

This application claims priority to China Patent Application No. 202411745268.8, filed on Nov. 29, 2024, the entire contents of which are incorporated herein by reference for all purposes.

### FIELD OF THE INVENTION

The present invention relates to a method and device for monitoring a DC bus capacitor, and more particularly to a method and device for monitoring a DC bus capacitor for a converter.

### BACKGROUND OF THE INVENTION

Capacitors are susceptible to rapid and significant performance degradation due to aging. Common degradation symptoms include a reduction in equivalent capacitance, an increase in equivalent series resistance (ESR), and an increase in leakage current. Such degradation adversely affects the operational characteristics of power electronic equipment, potentially leading to system malfunctions or failures.

As the reliability requirements for electronic devices become increasingly stringent, the function of monitoring the state of capacitors is introduced. By estimating the equivalent parameters of the capacitors in real-time, the aging status of the capacitors can be monitored. Therefore, the degradation of the capacitors is monitored timely, thereby preventing failures of the electronic equipment.

The conventional capacitor monitoring approaches are performed through hardware or software. If the capacitor is monitored through hardware approach, an additional hardware equipment is required, thereby increasing the cost and limiting the usage environment.

Therefore, there is a need of providing a monitoring method and device for monitoring a DC bus capacitor to obviate the drawbacks encountered from the prior arts.

### SUMMARY OF THE INVENTION

It is an object of the present disclosure to provide a monitoring method and device for monitoring a DC bus capacitor. In the present disclosure, each capacitance is assigned with a corresponding total weight coefficient, so as to improve the calculation accuracy of the monitoring capacitance. In addition, since the monitoring capacitance is calculated according to the capacitances and the total weight coefficients obtained in multiple preset cycles, the situation of that the monitoring capacitance calculated in a single preset cycle cannot reflect the current monitoring environment is avoided. Therefore, the applicability is improved.

In accordance with an aspect of the present disclosure, there is provided a monitoring method for monitoring a DC bus capacitor, wherein the DC bus capacitor is electrically connected to an output terminal of a converter, an input terminal of the converter is electrically connected to an AC bus. The method includes steps of: (a) in a preset cycle, sampling an input voltage and an input current at the input terminal and an output voltage at the output terminal, and utilizing the input voltage and the input current to obtain an input power; (b) filtering the input power and the output voltage to obtain an AC component of the input power and an AC component of the output voltage; (c) obtaining a DC component of the output voltage, and calculating a capacitance according to the DC component of the output voltage, the AC component of the input power and the AC component of the output voltage; (d) obtaining a total weight coefficient corresponding to the capacitance according to at least one of the AC component of the input power, the AC component of the output voltage and an operating temperature of the DC bus capacitor, wherein the total weight coefficient is the product of a plurality of weight coefficients; and (e) outputting a monitoring capacitance of the DC bus capacitor according to the plurality of the capacitance calculated and obtained in a plurality of the preset cycles and the plurality of the total weight coefficients corresponding to the plurality of capacitance.

In accordance with an aspect of the present disclosure, there is provided a monitoring device for monitoring a DC bus capacitor, the device includes a converter and a controller. An input terminal and an output terminal of the converter are electrically connected to an AC bus and the DC bus capacitor. The controller is configured to perform the monitoring method for monitoring the DC bus capacitor.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic circuit diagram illustrating a monitoring device for monitoring the DC bus capacitor according to an embodiment of the present disclosure;

FIG. 2 is a schematic flow chart illustrating a monitoring method for monitoring the DC bus capacitor according to an embodiment of the present disclosure;

FIG. 3 is a detailed schematic flow chart of the step S3 in FIG. 2;

FIG. 4 is a schematic waveform diagram showing the AC component of the output voltage and the AC component of the input power obtained by the controller of FIG. 1 in a preset cycle; and

FIG. 5 is a schematic waveform diagram showing the AC component of the output voltage obtained by the controller of FIG. 1 in a preset cycle.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

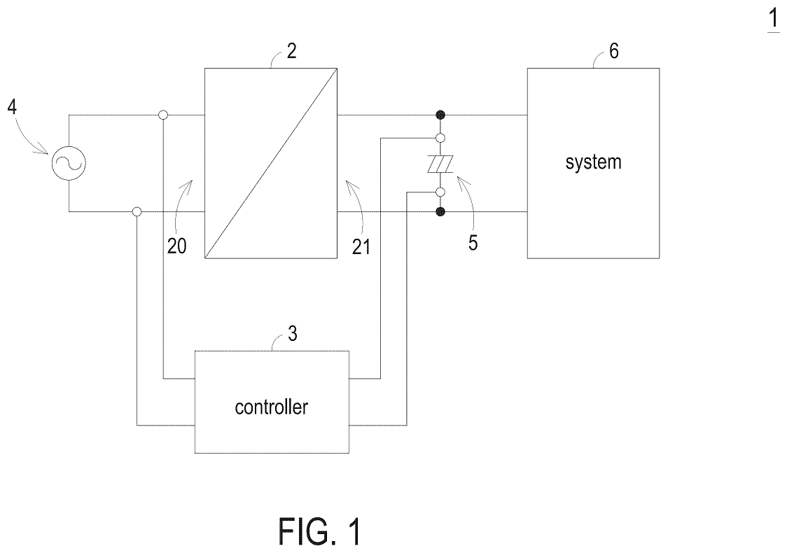

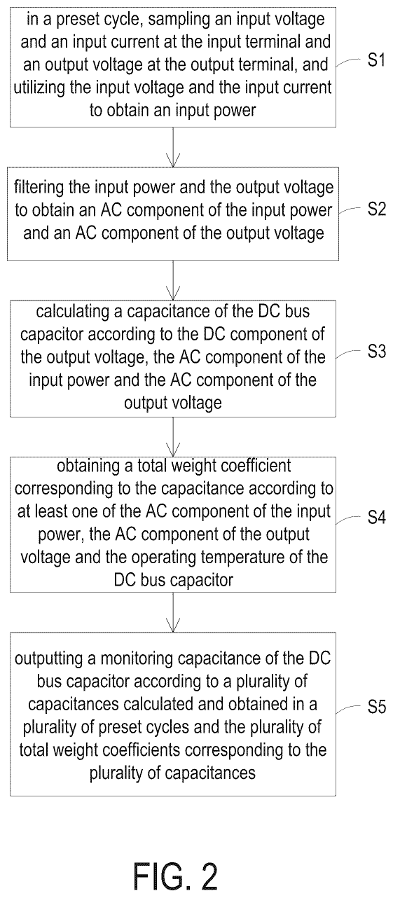

FIG. 1 is a schematic circuit diagram illustrating a monitoring device 1 of the DC bus capacitor according to an embodiment of the present disclosure. FIG. 2 is a schematic flow chart illustrating a monitoring method for monitoring the DC bus capacitor according to an embodiment of the present disclosure. As shown in FIGS. 1 and 2, the monitoring device 1 of the DC bus capacitor includes a converter 2 and a controller 3. An input terminal 20 and an output terminal 21 of the converter 2 are electrically connected to an AC bus and a DC bus capacitor 5 respectively. The controller 3 is configured to perform the monitoring method for monitoring the DC bus capacitor shown in FIG. 2. In an embodiment, the converter 2 is an AC/DC converter. In an embodiment, the AC bus is electrically connected to an AC power 4. In an embodiment, the converter 2 is electrically connected to a system 6, so a DC voltage outputted by the converter 2 is provided to the system 6.

Please refer to FIG. 2, the monitoring method of the present disclosure includes steps S1, S2, S3, S4 and S5. In the step S1, in a preset cycle, an input voltage and an input current at the input terminal and an output voltage at the output terminal are sampled, and the input voltage and the input current are utilized to obtain an input power. The preset cycle may be set according to actual requirements. In an embodiment, the preset cycle is half of a cycle of a fundamental wave of the input voltage.

In the step S2, the input power and the output voltage are filtered to obtain an AC component of the input power and an AC component of the output voltage. In an embodiment, a frequency range of the AC component of the input power and a frequency range of the AC component of the output voltage are both twice a frequency range of the fundamental wave of the input voltage. For example, a bandpass filter is utilized for filtering.

In the step S3, a DC component of the output voltage is obtained, and a capacitance of the DC bus capacitor 5 is calculated according to the DC component of the output voltage, the AC component of the input power and the AC component of the output voltage.

In the step S4, a total weight coefficient corresponding to the capacitance is obtained according to at least one of the AC component of the input power and the AC component of the output voltage. In an embodiment, the total weight coefficient is the product of a plurality of weight coefficients.

In the step S5, a monitoring capacitance of the DC bus capacitor 5 is outputted according to a plurality of capacitances calculated and obtained in a plurality of preset cycles and the plurality of total weight coefficients corresponding to the plurality of capacitances. In an embodiment, the plurality of capacitances calculated and obtained in the plurality of preset cycles are calibrated in consideration of the influence of environmental factors.

In the monitoring method and device for monitoring the DC bus capacitor of the present disclosure, each capacitance is assigned with a corresponding total weight coefficient, so as to improve the calculation accuracy of the monitoring capacitance. In addition, since the monitoring capacitance is calculated according to the capacitances and the total weight coefficients obtained in multiple preset cycles, the situation of that the monitoring capacitance calculated in a single preset cycle cannot reflect the current monitoring environment is avoided. Therefore, the applicability is improved.

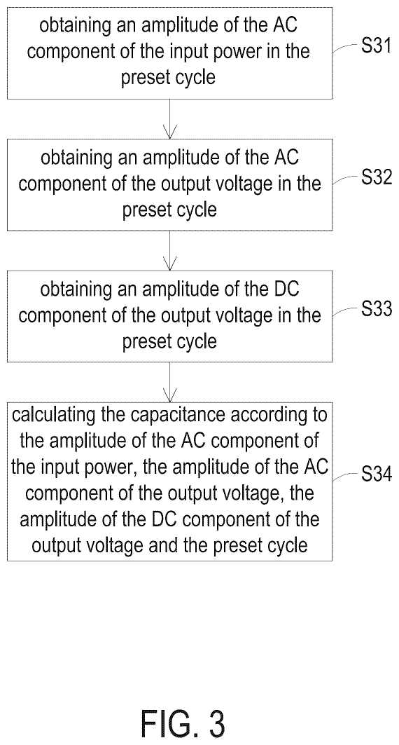

The calculation approach of the capacitance of the DC bus capacitor 5 of the step S3 of the present disclosure is introduced in detail as follow. In the present disclosure, the step S3 of the monitoring method includes steps S31, S32, S33 and S34. As shown in FIG. 3, in the step S31, in any one of the preset cycle, an amplitude of the AC component of the input power in the preset cycle is obtained. In the step S32, an amplitude of the AC component of the output voltage in the preset cycle is obtained. In the step S33, an amplitude of the DC component of the output voltage in the preset cycle is obtained. In the step S34, the capacitance is calculated according to the amplitude of the AC component of the input power, the amplitude of the AC component of the output voltage, the amplitude of the DC component of the output voltage and the preset cycle.

The capacitance calculated in the step S34 satisfies the following formula (1):

$$C = \frac{{P}_{in , ac}}{2 π {f}_{ω} * {u}_{dc , ac} * {u}_{dc , dc}} \qquad ( 1 )$$

Wherein C is the capacitance, u_{ac,dc} is the amplitude of the DC component of the output voltage in the preset cycle, P_{in,ac} is the amplitude of the AC component of the input power in the preset cycle, u_{ac,ac} is the amplitude of the AC component of the output voltage in the present cycle, and f_{ω} is a frequency corresponding to the preset cycle.

The total weight coefficient of the step S4 of the present disclosure may be a single weight coefficient or a product of a plurality of weight coefficients. The plurality of weight coefficients include, but are not limited to a first weight coefficient, a second weight coefficient, a third weight coefficient and a fourth weight coefficient. The approach for obtaining the first weight coefficient, the second weight coefficient, the third weight coefficient and the fourth weight coefficient are described as follows.

The first weight coefficient includes a plurality of first sub-weight coefficients, and each of the plurality of first sub-weight coefficients is correlated with a corresponding sinusoidal parameter. The sinusoidal parameter characterizes at least one of a sinusoidal degree of a waveform of the AC component of the input power and a sinusoidal degree of a waveform of the AC component of the output voltage. In an embodiment, the first weight coefficient is a product of the plurality of first sub-weight coefficients.

In specific, the range of the sinusoidal parameter determines the value of the first sub-weight coefficient, and the first sub-weight coefficient is between 0 and 1. When the sinusoidal parameter falls within a first sinusoidal range, the first sub-weight coefficient is 1; when the sinusoidal parameter exceeds the first sinusoidal range and falls within a second sinusoidal range, the first sub-weight coefficient is between 0 and 1; and when the sinusoidal parameter exceeds the second sinusoidal range, the first sub-weight coefficient is equal to 0. The first and second sinusoidal ranges of the present disclosure may be set according to actual requirement and are not limited.

In an embodiment, in the preset cycle, the AC component of the input power or the AC component of the output voltage have a plurality of sampling points. In an embodiment, the sinusoidal parameter is an absolute value of a quotient of the maximum value or minimum value of the AC component of the input power or the AC component of the output voltage in the preset cycle and the sum of all positive sampling points in the preset cycle, or the sinusoidal parameter is an absolute value of a quotient of the maximum value or minimum value of the AC component of the input power or the AC component of the output voltage in the preset cycle and the sum of all negative sampling points in the preset cycle. In another embodiment, the sinusoidal parameter is the sum of the maximum and minimum values of all sampling points of the AC component of the input power or the AC component of the output voltage in the preset cycle. In another embodiment, the sinusoidal parameter is the sum of all sampling points of the AC component of the input power or the AC component of the output voltage in the preset cycle.

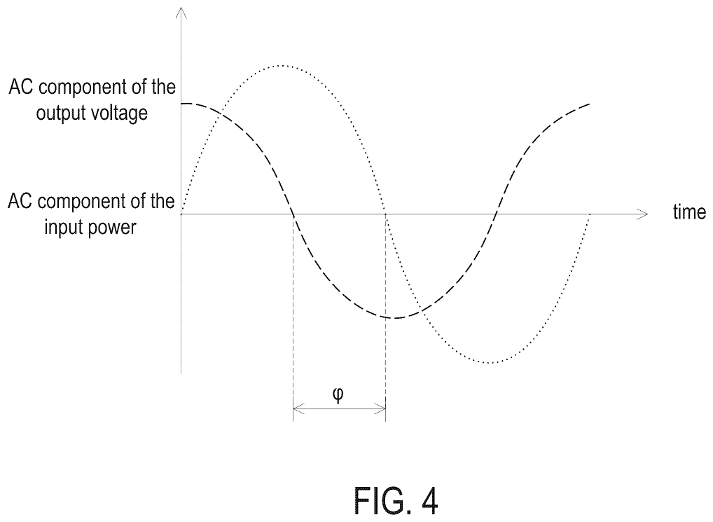

The second weight coefficient is correlated with a phase difference between the waveform of the AC component of the input power and the waveform of the AC component of the output voltage. In specific, the range of the phase difference determines the value of the second weight coefficient, and the second weight coefficient is between 0 and 1. Please refer to FIG. 4, FIG. 4 is a schematic waveform diagram showing the AC component of the output voltage and the AC component of the input power obtained by the controller 3 of FIG. 1 in a preset cycle. As shown in FIG. 4, there is a phase difference φ between the AC component of the input power and the AC component of the output voltage. When the phase difference φ falls within a first phase range, the second weight coefficient is 1; when the phase difference φ exceeds the first phase range and falls within a second phase range, the second weight coefficient is between 0 and 1; and when the phase difference φ exceeds the second phase range, the second weight coefficient is equal to 0. The first and second phase ranges of the present disclosure may be set according to actual requirement and are not limited. In an embodiment, the first phase range may be set to be close to 270 degrees, so when the phase difference between the AC component of the input power and the AC component of the output voltage is close to 270 degrees (that is, the AC component of the output voltage leads the AC component of the input power by close to 90 degrees), the second weight coefficient is 1. In an embodiment, the AC component of the output voltage and the AC component of the input power shown in FIG. 4 are obtained by filtering the output voltage of the converter 2 and the input power calculated by the input voltage and the input current in a preset cycle T. Therefore, the phase difference between the AC component of the input power and the AC component of the output voltage may be determined according to the number of sampling points between the zero-crossing points of the AC component waveform of the input power and the zero-crossing points of the AC component waveform of the output voltage.

The third weight coefficient is correlated with the input power of the AC bus electrically connected to the input terminal of the converter. Under the same operating conditions, such as constant temperature, the monitoring accuracy of the capacitance is positively correlated with a value of the input power. In specific, the third weight coefficient is positively correlated with a value of the input power of the AC bus electrically connected to the input terminal 20 of the converter, and the third weight coefficient is between 0 and 1. The more the input power increases, the more the third weight coefficient approaches 1. Conversely, the more the input power decreases, the more the third weight coefficient approaches 0. In an embodiment, with the rated power of the converter 2 as a reference, when the input power is equal to the rated power of the converter 2, the third weight coefficient is equal to 1, and the more the input power approaches the rated power of the converter 2, the more the third weight coefficient approaches 1. Conversely, the more the input power deviates from the rated power of the converter 2, the more the third weight coefficient approaches 0. In an embodiment, the amplitude of the input power may be determined based on the amplitude of the waveform of the AC component of the input power or the AC component of the output voltage, and a larger amplitude represents a higher input power.

The fourth weight coefficient is correlated with an operating temperature of the DC bus capacitor 5. Under the same operating conditions, for example, when the input power is the same, the detection accuracy of the capacitance is correlated with the temperature. In specific, the range of the operating temperature of the DC bus capacitor 5 determines the value of the fourth weight coefficient, and the fourth weight coefficient is between 0 and 1. When the operating temperature of the DC bus capacitor 5 falls within a first temperature range, the fourth weight coefficient is 1; and when the operating temperature of the DC bus capacitor 5 exceeds the first temperature range, the fourth weight coefficient is between 0 and 1. The more the operating temperature of the DC bus capacitor 5 approaches the first temperature range, the more the fourth weight coefficient approaches 1. Conversely, the more the operating temperature of the DC bus capacitor 5 deviates from the first temperature range, the more the fourth weight coefficient approaches 0. In an embodiment, the first temperature range is 20° C.-22° C., therefore, when the operating temperature of the DC bus capacitor 5 falls within 20° C.-22° C., the fourth weight coefficient is 1.

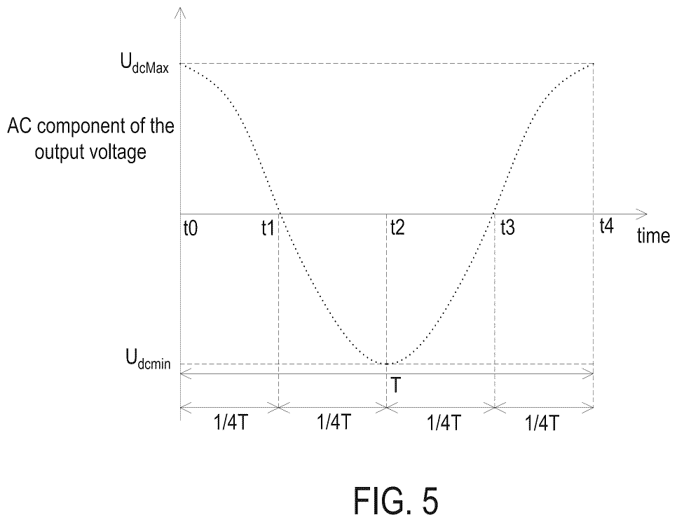

FIG. 5 is a schematic waveform diagram showing the AC component of the output voltage obtained by the controller 3 of FIG. 1 in a preset cycle T. FIG. 5 shows the AC component of the output voltage as an example for illustrating how the sinusoidal degree of the waveform of the AC component of the output voltage can be utilized to obtain its sinusoidal parameter, which is then used to obtain the first sub-weight coefficient. The AC component of the output voltage shown in FIG. 5 is obtained by filtering the output voltage of the converter 2 sampled in a preset cycle T, wherein the sampling frequency is f0 (Hz), and the frequency of the preset cycle T is f1 (Hz). Therefore, in a preset cycle T, the AC component of the output voltage has F sampling points, wherein F is f0/f1. In the embodiment shown in FIG. 5, the time length from time t0 to t4 is a preset cycle T, and the time length from time t0 to t1, the time length from time t1 to t2, the time length from time t2 to t3, and the time length from time t3 to t4 are all one quarter of the preset cycle T.

As shown in FIG. 5, the maximum value of all sampling points of the AC component of the output voltage in the preset period T is U_{dcMax}, and the minimum value of all sampling points of the AC component of the output voltage in the preset period Tis U_{dcmin}. The sum of all sampling points of the AC component of the output voltage from time t0 to t1 is U_{dcSum0}, the sum of all sampling points of the AC component of the output voltage from time t1 to t2 is U_{dcSum1}, the sum of all sampling points of the AC component of the output voltage from time t2 to t3 is U_{dcSum2}, the sum of all sampling points of the AC component of the output voltage from time t3 to t4 is U_{dcSum3}, and the sum of all sampling points of the AC component of the output voltage from time t0 to t4 is U_{dcSum}, where U_{dcSum}=U_{dcSum0}+U_{dcSum1}+U_{dcSum2}+U_{dcSum3}.

In an embodiment, the sinusoidal parameter is the sum of the maximum and minimum values of all sampling points of the AC component of the output voltage in the preset period T. In specific, in this embodiment, the sinusoidal parameter is U_{dcMax}+U_{dcmin}. When U_{dcMax}+U_{dcmin} falls within the first sinusoidal range, the first sub-weight coefficient is 1. Ideally, U_{dcMax}+U_{dcmin} is equal to 0, but a certain margin needs to be considered in practice. In this embodiment, a second sinusoidal range is also provided, and the second sinusoidal range is larger than the first sinusoidal range. When U_{dcMax}+U_{dcmin} does not fall within the first sinusoidal range and falls within the second sinusoidal range, the first sub-weight coefficient is between 0 and 1. The closer U_{dcMax}+U_{dcmin} is to the first sinusoidal range, the closer the first sub-weight coefficient is to 1, and the closer U_{dcMax}+U_{dcmin} is to the boundary of the second sinusoidal range, the closer the first sub-weight coefficient is to 0. When U_{dcMax}+U_{dcmin} exceeds the second sinusoidal range, the first sub-weight coefficient is equal to 0.

In an embodiment, the sinusoidal parameter is the sum of all sampling points of the AC component of the output voltage in a preset cycle T. In specific, the sum of all sampling points of the AC component of the output voltage from time t0 to time t4 is U_{dcSum}, that is, in this embodiment, the sinusoidal parameter is U_{dcSum}. Ideally, U_{dcSum} is equal to 0, but a certain margin needs to be considered in practice. When U_{dcSum} falls within the first sinusoidal range, the first sub-weight coefficient is 1. In this embodiment, a second sinusoidal range is also provided, and the second sinusoidal range is larger than the first sinusoidal range. When U_{dcSum} exceeds the first sinusoidal range and falls within the second sinusoidal range, the first sub-weight coefficient is between 0 and 1. The closer U_{dcSum} is to the first sinusoidal range, the closer the first sub-weight coefficient is to 1, and the closer U_{dcSum} is to the boundary of the second sinusoidal range, the closer the first sub-weight coefficient is to 0. When U_{dcSum} exceeds the second sinusoidal range, the first sub-weight coefficient is equal to 0.

In an embodiment, the sinusoidal parameter is an absolute value of a quotient of the maximum value or minimum value of the AC component of the output voltage and the sum of all positive sampling points in a half cycle of the preset cycle, or the sinusoidal parameter is an absolute value of a quotient of the maximum value or minimum value of the AC component of the output voltage and the sum of all negative sampling points in a half cycle of the preset cycle. In specific, the maximum value of the AC component of the output voltage from time t0 to t4 is U_{dcMax}, and the sum of all positive sampling points in the half period of the preset cycle is (U_{dcSum0}+U_{dcSum3}). Therefore, in this embodiment, the sinusoidal parameter is U_{dcMax}/(U_{dcSum0}+U_{dcSum3}). Ideally, U_{dcMax}/(U_{dcSum0}+U_{dcSum3}) is π×f1/f0, but a certain margin needs to be considered in practice. When U_{dcMax}/(U_{dcSum0}+U_{dcSum3}) falls within the first sinusoidal range, the first sub-weight coefficient is 1. In this embodiment, a second sinusoidal range is also provided, and the second sinusoidal range is larger than the first sinusoidal range. When U_{dcMax}/(U_{dcSum0})+U_{dcSum3}) exceeds the first sinusoidal range and falls within the second sinusoidal range, the first sub-weight coefficient is between 0 and 1. The closer U_{dcMax}/(U_{dcSum0}+U_{dcSum3}) is to the first sinusoidal range, the closer the first sub-weight coefficient is to 1, the closer U_{dcMax}/(U_{dcSum0}+U_{dcSum3}) is to the second sinusoidal range boundary, the closer the first sub-weight coefficient is to 0. When U_{dcMax}/(U_{dcSum0}+U_{dcSum3}) exceeds the first sinusoidal range, the first sub-weight coefficient is equal to 0.

In an embodiment, the sinusoidal parameter is correlated with the accumulated number of the sampling points in the preset cycle. For example, at time t1, if the accumulated number of the sampling points is ┌F/4┐, the first sub-weight coefficient is 1. If the accumulated number of the sampling points is ┌F/4┐±1, the first sub-weight coefficient is between 0 and 1. If the accumulated number of the sampling points is not ┌F/4┐ or ┌F/4┐±1, the first sub-weight coefficient is 0. The first sub-weight coefficient may be obtained in a similar manner at time t1, time t2, time t3 and time t4, and the detailed descriptions thereof are omitted herein.

In the monitoring method for monitoring the DC bus capacitor of the present disclosure, the ultimate goal is to confirm the health of the capacitor. Since the capacitances calculated in each preset cycle is under different environmental conditions, which impact the calculated capacitances, it is necessary to standardize them under the same reference environment for accurate comparison. That is, the capacitances calculated in each preset cycle needs to be calibrated, including temperature calibration and power calibration, so that the health of the capacitor can be accurately reflected after calibration.

In an embodiment, the monitoring method for monitoring the DC bus capacitor of the present disclosure further includes: obtaining a first relationship curve between the capacitance and temperature of the DC bus capacitor (it should be understood that this can be obtained in advance by measurement or according to the parameters of the capacitor manufacturer); setting a reference temperature, that is, the capacitance calculated in each preset cycle is calibrated with the reference temperature; in each preset cycle, obtaining an operating temperature of the DC bus capacitor, and obtaining a temperature calibration coefficient of each preset cycle according to the operating temperature, the reference temperature and the first relationship curve; multiplying the capacitance calculated in each preset cycle and the corresponding temperature calibration coefficient to obtain the capacitance with temperature calibration, wherein the temperature calibration coefficient is the ratio of the capacitance corresponding to the reference temperature (e.g., room temperature 20° C.) under the first relationship curve to the capacitance corresponding to the operating temperature under the first relationship curve. After all the capacitances calculated in the preset cycle are calibrated with the reference temperature, the monitoring capacitance obtained accordingly can reflect the health of the capacitor and is more meaningful for reference.

In an embodiment, the monitoring method for monitoring the DC bus capacitor of the present disclosure further includes: obtaining a second relationship curve between the capacitance of the DC bus capacitor and input power at the input terminal (it should be understood that this can be obtained in advance by measurement); setting a reference power, that is, the capacitance calculated in each preset cycle is calibrated with the reference power; in each preset cycle, obtaining an input power, and obtaining a power calibration coefficient of each preset cycle according to the input power, the reference power and the second relationship curve; multiplying the capacitance calculated in each preset cycle and the corresponding power calibration coefficient to obtain the capacitance with power calibration, wherein the power calibration coefficient is the ratio of the capacitance corresponding to the reference power under the relationship curve to the capacitance corresponding to the actual input power. After all the capacitances calculated in the preset cycle are calibrated with the reference power, the monitoring capacitance obtained accordingly can reflect the health of the capacitor and is more meaningful for reference. It should be noted that in some embodiments, temperature calibration and power calibration may be performed simultaneously. The calibrated capacitance is then calculated accordingly with the total weight coefficient to obtain the final monitoring capacitance monitoring.

The approach of obtaining the monitoring capacitance in the step S5 of the monitoring method is exemplified as follow. At the end of each preset cycle, the monitoring method for monitoring the DC bus capacitor of the present disclosure outputs a corresponding monitoring capacitance. The calculation formulas for the monitoring capacitance Cout(n) outputted at the end of the nth preset cycle are described as follows.

When n is equal to 1, the monitoring capacitance at the end of the first preset cycle is Cout(1), and it satisfies the following formula (2).

$$Cout ( 1 ) = \frac{C ( 1 ) * K ( 1 ) + C ( 0 )}{1 + K ( 1 )} \qquad ( 2 )$$

Wherein C(1) is the capacitance calculated in the first preset cycle, and further, C(1) is the capacitance calculated in the first preset cycle after at least one of the temperature calibration and the power calibration is performed, K(1) is the total weight coefficient corresponding to the capacitance of the first preset cycle, and C(0) is the factory value of the capacitance of the DC bus capacitor 5. In an embodiment, the total weight coefficient is the product of the first weight coefficient, the second weight coefficient, the third weight coefficient and the fourth weight coefficient.

When n is equal to 2, the monitoring capacitance at the end of the second preset cycle is Cout(2), and it satisfies the following formula (3).

$$Cout ( 2 ) = \frac{Cout ( 1 ) * K ( 1 ) + C ( 2 ) * K ( 2 )}{K ( 1 ) + K ( 2 )} \qquad ( 3 )$$

C(2) is the capacitance calculated in the second preset cycle, and further, C(2) is the capacitance calculated in the second preset cycle after at least one of the temperature calibration and the power calibration is performed, K(2) is the total weight coefficient corresponding to the capacitance of the second preset cycle.

When n is greater than 3, the monitoring capacitance at the end of the nth is Cout(n), and it satisfies the following formula (4).

$$Cout ( n ) = \frac{Cout ( n - 1 ) * K ( n - 1 ) + C ( n ) * K ( n )}{K ( n - 1 ) + K ( n - 2 )} \qquad ( 4 )$$

Cout(n−1) is the monitoring capacitance at the end of the n−1th preset cycle, K(n−1) is the total weight coefficient corresponding to the capacitance of the n−1th preset cycle, C(n) is the capacitance calculated in the nth preset cycle, K(n) is the total weight coefficient corresponding to the capacitance of the nth preset cycle, and K(n−2) is the total weight coefficient corresponding to the capacitance of the n−2th preset cycle.

From the above descriptions, the present disclosure provides a monitoring method and a device for monitoring the DC bus capacitor. In the present disclosure, each capacitance is assigned with a corresponding total weight coefficient, so as to improve the calculation accuracy of the monitoring capacitance. In addition, since the monitoring capacitance is calculated according to the capacitances and the total weight coefficients obtained in multiple preset cycles, the situation of that the monitoring capacitance calculated in a single preset cycle cannot reflect the current monitoring environment is avoided. Therefore, the applicability is improved.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A monitoring method for monitoring a DC bus capacitor, wherein the DC bus capacitor is electrically connected to an output terminal of a converter, an input terminal of the converter is electrically connected to an AC bus, the method comprises steps of:
(a) in a preset cycle, sampling an input voltage and an input current at the input terminal and an output voltage at the output terminal, and utilizing the input voltage and the input current to obtain an input power;
(b) filtering the input power and the output voltage to obtain an AC component of the input power and an AC component of the output voltage;
(c) obtaining a DC component of the output voltage, and calculating a capacitance according to the DC component of the output voltage, the AC component of the input power and the AC component of the output voltage;
(d) obtaining a total weight coefficient corresponding to the capacitance according to at least one of the AC component of the input power, the AC component of the output voltage and an operating temperature of the DC bus capacitor, wherein the total weight coefficient is the product of a plurality of weight coefficients; and
(e) outputting a monitoring capacitance of the DC bus capacitor according to a plurality of the capacitances calculated and obtained in a plurality of the preset cycles and the plurality of the total weight coefficients corresponding to the plurality of capacitances.

2. The monitoring method according to claim 1, wherein a frequency range of the AC component of the input power and a frequency range of the AC component of the output voltage are both twice a frequency range of a fundamental wave of the input voltage.

3. The monitoring method according to claim 1, wherein the preset cycle is half of a cycle of a fundamental wave cycle of the input voltage.

4. The monitoring method according to claim 1, wherein the plurality of weight coefficients comprise a first weight coefficient, the first weight coefficient comprises a plurality of first sub-weight coefficients, and each of the plurality of first sub-weight coefficients is correlated with a sinusoidal parameter, wherein the sinusoidal parameter characterizes at least one of a sinusoidal degree of a waveform of the AC component of the input power and a sinusoidal degree of a waveform of the AC component of the output voltage, wherein in the preset cycle, the AC component of the output voltage has a plurality of sampling points, and the AC component of the input power has a plurality of sampling points.

5. The monitoring method according to claim 4, wherein when the sinusoidal parameter falls within a first sinusoidal range, the first sub-weight coefficient is 1; when the sinusoidal parameter exceeds the first sinusoidal range and falls within a second sinusoidal range, the first sub-weight coefficient is between 0 and 1; and when the sinusoidal parameter exceeds the second sinusoidal range, the first sub-weight coefficient is equal to 0.

6. The monitoring method according to claim 4, wherein at least one of the sinusoidal parameters is an absolute value of a quotient of a maximum value or a minimum value of the AC component of the input power or the AC component of the output voltage in the preset cycle and a sum of all positive sampling points in the preset cycle, or the sinusoidal parameter is an absolute value of a quotient of a maximum value or a minimum value of the AC component of the input power or the AC component of the output voltage in the preset cycle and a sum of all negative sampling points in the preset cycle.

7. The monitoring method according to claim 4, wherein at least one of the said sinusoidal parameters is a sum of a maximum value and a minimum value of all the plurality of sampling points of the AC component of the input power or the AC component of the output voltage in the preset cycle.

8. The monitoring method according to claim 4, wherein at least one of the sinusoidal parameters is a sum of all the plurality of sampling points of the AC component of the input power or the AC component of the output voltage in the preset cycle.

9. The monitoring method according to claim 1, wherein the plurality of weight coefficients comprise a second weight coefficient, the second weight coefficient is correlated with a phase difference between a waveform of the AC component of the input power and a waveform of the AC component of the output voltage.

10. The monitoring method according to claim 9, wherein when the phase difference falls within a first phase range, the second weight coefficient is 1; when the phase difference exceeds the first phase range and falls within a second phase range, the second weight coefficient is between 0 and 1; and when the phase difference exceeds the second phase range, the second weight coefficient is equal to 0.

11. The monitoring method according to claim 1, wherein the plurality of weight coefficients comprise a third weight coefficient, the third weight coefficient is positively correlated with a value of the input power, and the third weight coefficient is between 0 and 1.

12. The monitoring method according to claim 1, wherein the plurality of weight coefficients comprise a fourth weight coefficient, the fourth weight coefficient is correlated with an operating temperature of the DC bus capacitor, when the operating temperature of the DC bus capacitor falls within a first temperature range, the fourth weight coefficient is 1; and when the operating temperature of the DC bus capacitor exceeds the first temperature range, the fourth weight coefficient is between 0 and 1, and the closer the operating temperature of the DC bus capacitor is to the first temperature range, the closer the fourth weight coefficient is to 1.

13. The monitoring method according to claim 1, wherein the step (c) further comprises steps of:
(c1) in any one of the preset cycle, obtaining an amplitude of the AC component of the input power;
(c2) obtaining an amplitude of the AC component of the output voltage in the preset cycle;
(c3) obtaining an amplitude of the DC component of the output voltage in the preset cycle; and
(c4) calculating the capacitance according to the amplitude of the AC component of the input power, the amplitude of the AC component of the output voltage, the amplitude of the DC component of the output voltage and the preset cycle.

14. The monitoring method according to claim 13, wherein the capacitance satisfies the following formula:
$$C = \frac{{P}_{in , ac}}{2 π {f}_{ω} * {u}_{dc , ac} * {u}_{dc , dc}}$$
wherein C is the capacitance, u_{ac,dc} is the amplitude of the DC component of the output voltage in the preset cycle, P_{in,ac} is the amplitude of the AC component of the input power in the preset cycle, u_{dc,ac} is the amplitude of the AC component of the output voltage in the present cycle, and f_{ω} is a frequency corresponding to the preset cycle.

15. The monitoring method according to claim 1, further comprising steps of:
obtaining a first relationship curve between the capacitance of the DC bus capacitor and a temperature;
setting a reference temperature;
in each of the plurality of preset cycles:
obtaining the operating temperature of the DC bus capacitor;
obtaining a temperature correction coefficient according to the operating temperature, the reference temperature and the first relationship curve; and
obtaining the capacitance after temperature correction according to the product of the calculated capacitance and the temperature correction coefficient.

16. The monitoring method according to claim 1, further comprising steps of:
obtaining a second relationship curve between the capacitance of the DC bus capacitor and the input power;
setting a reference power;
in each of the plurality of preset cycles:
obtaining a power correction coefficient according to the input power,
the reference power and the second relationship curve; and
obtaining the capacitance after power correction according to the product of the calculated capacitance and the power correction coefficient.

17. A monitoring device for monitoring a DC bus capacitor, comprising:
a converter, wherein an input terminal of the converter is electrically connected to an AC bus, and an output terminal of the converter is electrically connected to the DC bus capacitor; and
a controller, configured to perform a monitoring method comprising steps of:
(a) in a preset cycle, sampling an input voltage and an input current at the input terminal and an output voltage at the output terminal, and utilizing the input voltage and the input current to obtain an input power;
(b) filtering the input power and the output voltage to obtain an AC component of the input power and an AC component of the output voltage;
(c) obtaining a DC component of the output voltage, and calculating a capacitance according to the DC component of the output voltage, the AC component of the input power and the AC component of the output voltage;
(d) obtaining a total weight coefficient corresponding to the capacitance according to at least one of the AC component of the input power, the AC component of the output voltage and an operating temperature of the DC bus capacitor, wherein the total weight coefficient is the product of a plurality of weight coefficients; and
(e) outputting a monitoring capacitance of the DC bus capacitor according to a plurality of the capacitances calculated and obtained in a plurality of the preset cycles and the plurality of the total weight coefficients corresponding to the plurality of capacitances.

18. The monitoring device according to claim 17, wherein the plurality of weight coefficients comprise at least one of a first weight coefficient, a second weight coefficient, a third weight coefficient and a fourth weight coefficient,
wherein the first weight coefficient comprises a plurality of first sub-weight coefficients, and each of the plurality of first sub-weight coefficients is correlated with a sinusoidal parameter, wherein the sinusoidal parameter characterizes at least one of a sinusoidal degree of a waveform of the AC component of the input power and a sinusoidal degree of a waveform of the AC component of the output voltage, wherein in the preset cycle, the AC component of the output voltage has a plurality of sampling points, and the AC component of the input power has a plurality of sampling points;
wherein the second weight coefficient is correlated with a phase difference between a waveform of the AC component of the input power and a waveform of the AC component of the output voltage;
wherein the third weight coefficient is positively correlated with a value of the input power, and the third weight coefficient is between 0 and 1; and
wherein the fourth weight coefficient is correlated with an operating temperature of the DC bus capacitor, when the operating temperature of the DC bus capacitor falls within a first temperature range, the fourth weight coefficient is 1; and when the operating temperature of the DC bus capacitor exceeds the first temperature range, the fourth weight coefficient is between 0 and 1, and the closer the operating temperature of the DC bus capacitor is to the first temperature range, the closer the fourth weight coefficient is to 1.

19. The monitoring device according to claim 17, wherein the step (c) further comprises steps of:
(c1) in any one of the preset cycle, obtaining an amplitude of the AC component of the input power;
(c2) obtaining an amplitude of the AC component of the output voltage in the preset cycle;
(c3) obtaining an amplitude of the DC component of the output voltage in the preset cycle; and
(c4) calculating the capacitance according to the amplitude of the AC component of the input power, the amplitude of the AC component of the output voltage, the amplitude of the DC component of the output voltage and the preset cycle.

20. The monitoring device according to claim 17, wherein the monitoring method further comprises steps of:
obtaining a first relationship curve between the capacitance of the DC bus capacitor and a temperature;
setting a reference temperature;
in each of the plurality of preset cycles:
obtaining the operating temperature of the DC bus capacitor;
obtaining a temperature correction coefficient according to the operating temperature, the reference temperature and the first relationship curve; and
obtaining the capacitance after temperature correction according to the product of the calculated capacitance and the temperature correction coefficient;
or wherein the monitoring method further comprises steps of:
obtaining a second relationship curve between the capacitance of the DC bus capacitor and the input power;
setting a reference power;
in each of the plurality of preset cycles:
obtaining a power correction coefficient according to the input power, the reference power and the second relationship curve; and
obtaining the capacitance after power correction according to the product of the calculated capacitance and the power correction coefficient.
